(19) United States
(12) Patent Application Publication
(10) Pub. No.: US 2010/0068659 A1
(43) Pub. Date: Mar. 18, 2010

(54) EXPOSURE APPARATUS AND DEVICE MANUFACTURING METHOD

(75) Inventor: Zenichi Hamaya, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/413,394

(22) Filed: Mar. 27, 2009

(30) Foreign Application Priority Data
Mar. 28, 2008 (JP) 2008-088786

(51) Int. Cl. G03F 7/20; G03B 27/42

(52) U.S. Cl. 430/325; 355/53

(57) ABSTRACT

An exposure apparatus of the present invention is an EUV exposure apparatus 700 which is configured to expose a circuit pattern formed on a reticle 6 onto a wafer 9 in a vacuum environment. The EUV exposure apparatus 700 comprises a plurality of vacuum chambers 1 to 5 which separate inside of the EUV exposure apparatus 700 into a plurality of areas, and a wire electrode array 30 having a plurality of parallel wire electrodes. The wire electrode array 30 is placed at openings 25 to 28 through which exposure light passes at a boundary between adjacent vacuum chambers, and has a first wire electrode group to which an alternating voltage Va of a first phase is applied and a second wire electrode group to which an alternating voltage Vb of a second phase differing from the first phase is applied.

### BACKGROUND OF THE INVENTION

1. Field of the Invention

The present invention relates to an exposure apparatus, and more particular to an exposure apparatus which effectively prevents pollution of an optical element in the apparatus.

2. Description of the Related Art

Recently, exposure light which is used for a light lithography technology for manufacturing semiconductors is shortened in wavelength, and progresses from i-line or g-line to KrF excimer laser light or ArF excimer laser light. Shortening the exposure light can transfer a finer mask pattern onto a wafer.

However, in order to expose a pattern which has a fine line width, a lithography technology in which ultraviolet light is used has limitations in principle. Therefore, recently, an EUV lithography technology using extreme ultraviolet light (EUV light, wavelength of 13 to 20 nm) whose wavelength is shorter than that of ultraviolet light is attracting attention.

A typical wavelength used as the EUV light is 13.5 nm. Therefore, a resolution extremely higher than that of the conventional light lithography technology can be realized. However, at the same time, the EUV light has a property that it is easily absorbed in the material. Therefore, like the conventional lithography technology in which the ultraviolet light is used as a light source, when the reduced exposure is performed using a refracting optical system, the EUV light may be absorbed by a glass material and an amount of light which reaches an object to be exposed such as a wafer is extremely low. Therefore, when the exposure is performed by using the EUV light, the configuration of the reduced exposure using the reflecting optical system is necessary.

The EUV light which is used for the EUV exposure apparatus is absorbed by the atmosphere inside the apparatus. In particular, oxygen or moisture strongly absorbs the EUV light. Therefore, in order to maintain the transmittance of the EUV light at a high level, it is necessary to make a vacuum state in a chamber using a vacuum pump or the like.

In exposing a circuit pattern in a semiconductor exposure apparatus, a photosensitizing agent called a resist needs to be coated on a wafer surface. During the exposure, the exposure light and the resist coated on the wafer react to generate emitted gas such as hydrocarbon. In the EUV exposure apparatus, since the energy of the EUV light is strong, a large amount of the emitted gas is generated.

The emitted gas is scattered from the wafer to a projection optical system space. If it is irradiated by the exposure light on an optical element surface such as a multilayer mirror, it adheres to the optical element surface as a contaminant. If the emitted gas is a hydrocarbon, a carbon adheres to the optical element surface. The contaminant adhered to the optical element absorbs the EUV light and reduces the reflectance of the optical element. When the reflectance of the optical element is reduced, the throughput is led to be reduced.

Laser plasma that is one method of the EUV light source generates the EUV light from a target material by irradiating high intensity pulse laser light onto the target material. However, it also generates a particle called debris. The debris is scattered to the light source space and pollutes or damages the optical element, and it causes the reduction of reflectance. If the debris is scattered to an illumination optical system space, the optical element inside the illumination optical system is polluted.

In the EUV exposure apparatus, in order to maintain the light intensity of the EUV light, a multilayer mirror is provided in the light source space, the illumination optical system space, and the projection optical system space to constitute a reflecting optical system. It is known that a secondary electron is emitted when the EUV light is irradiated onto the multilayer mirror. When the secondary electron adheres to the optical element, the optical element is polluted and the reflectance is reduced.

In the EUV exposure apparatus, there is a possibility that a dust particle is scattered from a moving unit of a stage inside the apparatus chamber or the like. The particle also moves from the stage space to the projection optical system space and adheres to the optical element to reduce the optical performance.

In addition, there is a possibility that a particle is generated by slide or friction such as the movement of a robot hand or a gate valve during the transfer of the reticle or the wafer to the apparatus chamber, and that it adheres to the reticle or the wafer. The dust particle adhered to the reticle or the wafer may be scattered to the space in which the optical element is placed after the reticle or the wafer is transferred into the apparatus chamber. Thus, the dust particle generated outside the apparatus chamber may be carried inside the apparatus chamber and adhere onto the optical element surface inside the apparatus chamber to deteriorate the optical performance.

For example, Japanese Patent Laid-Open No. 2005-43895 discloses a method for providing a thin film at the boundary between a wafer stage space and a projection optical system space in order to prevent emitted gas generated from a resist from intruding to the projection optical system space.

In the method of Japanese Patent Laid-Open No. 2005-43895, it is possible that the movement of the emitted gas or the dust particle is physically blocked by the thin film. However, since the thickness of the thin film is equal to or less than 100 nm or is extremely thin, it is extremely difficult to manufacture the thin film. Furthermore, since the thin film has a thickness that is equal to or less than 100 nm, a supporting mechanism such as a wire is necessary. Therefore, the thin film needs to be manufactured including the wire that is a supporting mechanism and it takes much cost since the number of the processes at the time of manufacturing is large. Even if the thickness of the thin film is several hundred nm, the transmittance of the EUV light whose wavelength is 13.5 nm is around 50%. Therefore, compared to the case where there is no thin film, the transmittance is not adequately maintained.

The thin film is polluted by the adhesion of the emitted gas or the particle to the thin film, and the performance deterioration of the thin film is unavoidable. Since the cleaning of the thin film itself may be difficult, the exchange of the thin film is necessary and the throughput is led to be reduced.

As described above, the conventional technology can not protect an optical element from the pollution by preventing a particle such as emitted gas, debris, a secondary electron, a dust particle, or the like from moving in and out of each unit in the EUV exposure apparatus with the transmittance of the exposure light maintained.

### BRIEF SUMMARY OF THE INVENTION

The present invention provides an exposure apparatus which effectively prevents the pollution of an optical element inside the apparatus while the transmittance of the exposure light is maintained. The present invention also provides a device manufacturing method with high accuracy using the exposure apparatus.

An exposure apparatus as one aspect of the present invention is an exposure apparatus configured to expose a circuit pattern formed on an original plate onto a substrate in a vacuum environment. The exposure apparatus comprises a plurality of vacuum chambers which separate inside of the exposure apparatus into a plurality of areas and a wire electrode array having a plurality of parallel wire electrodes. The wire electrode array is placed at an opening through which exposure light passes at a boundary between the adjacent vacuum chambers, and has a first wire electrode group to which an alternating voltage of a first phase is applied and a second wire electrode group to which an alternating voltage of a second phase differing from the first phase is applied.

A device manufacturing method as another aspect of the present invention comprises the steps of exposing a substrate using the exposure apparatus and developing the exposed substrate.

Further features and aspects of the present invention will become apparent from the following description of exemplary embodiments with reference to the attached drawings.

### BRIEF DESCRIPTION OF THE DRAWINGS

FIG. 1 is a schematic configuration diagram of an exposure apparatus in the present embodiment.

FIG. 2 is a configuration diagram of a wafer stage space and a projection optical system space in an exposure apparatus of embodiment 1.

FIG. 3 is a configuration diagram of a wire electrode array which is constituted by two wire electrode groups provided in an exposure apparatus of embodiment 1.

FIG. 4 is a configuration diagram of a wire electrode array which is constituted by three wire electrode groups provided in an exposure apparatus of embodiment 1.

FIG. 5 is a waveform diagram of an alternating voltage which is applied to a wire electrode array constituted by two wire electrode groups shown in FIG. 3.

FIG. 6 is a waveform diagram of an alternating voltage which is applied to a wire electrode array constituted by three wire electrode groups shown in FIG. 4.

FIG. 7 is an illustration of an effect of a wire electrode array which is constituted by two wire electrode groups.

FIG. 8 is a configuration diagram of an opening through which exposure light passes in an exposure apparatus of embodiment 1.

FIG. 9 is a configuration diagram of a wafer stage space and a projection optical system space in an exposure apparatus of embodiment 2.

FIG. 10 is a configuration diagram of a wafer stage space and a projection optical system space in an exposure apparatus of embodiment 3.

FIG. 11 is a configuration diagram of a wafer stage space and a projection optical system space in an exposure apparatus of embodiment 4.

### DETAILED DESCRIPTION OF THE EMBODIMENTS

Exemplary embodiments of the present invention will be described below with reference to the accompanied drawings. In each of the drawings, the same elements will be denoted by the same reference numerals and the descriptions thereof will be omitted.

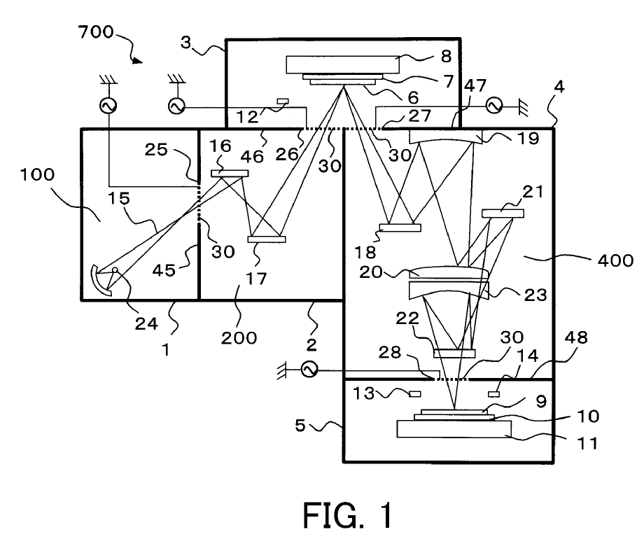

First, an exposure apparatus in the present invention will be schematically described. FIG. 1 is a schematic configuration diagram of an exposure apparatus in the present embodiment.

An EUV exposure apparatus 700 is an exposure apparatus which exposes a circuit pattern formed on an original plate (a reticle) onto a substrate (a wafer) in a vacuum environment. The EUV exposure apparatus 700 is provided with a plurality of vacuum chambers 1 to 5 which separate an inside of the exposure apparatus into a plurality of areas.

The vacuum chamber 1 constitutes a light source space in which a light source 100 is housed. The vacuum chamber 2 constitutes an illumination optical system space in which an illumination optical system 200 is housed. The vacuum chamber 3 constitutes a reticle stage space in which a reticle stage 8 is housed. The vacuum chamber 4 constitutes a projection optical system space in which a projection optical system 400 is housed. The vacuum chamber 5 constitutes a wafer stage space in which a wafer stage 11 is housed.

The vacuum chamber 3 constituting the reticle stage space is provided with a reticle holder 7 which holds a reticle 6 and a reticle stage 8 which mounts the reticle holder 7. The vacuum chamber 3 is also provided with a reticle alignment optical system 12 which is used for aligning the reticle 6.

The vacuum chamber 5 constituting the wafer stage space is provided with a wafer holder 10 which holds a wafer 9 and a wafer stage 11 which mounts the wafer holder 10. The vacuum chamber 5 is also provided with a wafer alignment optical system 13 which is used for aligning the wafer 9 and a focus position detection mechanism 14.

EUV light 15 emitted from the light source 100 is irradiated onto the reticle 6 via illumination optical system mirrors 16 and 17 which are provided inside the vacuum chamber 2. The EUV light 15 reflected by the reticle 6 is irradiated onto the wafer 9 via projection optical system mirrors 18 to 23 (multilayer mirrors) which are provided inside the vacuum chamber 4.

There are several kinds of light sources 100. A laser generating plasma light source that is one of the light sources is capable of emitting light which has substantially only a necessary wavelength band by selecting a target material 24. For example, when Xe, as a target material, is ejected from a pulse nozzle and a plasma is generated by irradiating a pulse laser to it, EUV light which has a wavelength 13 to 14 nm (for example, 13.5 nm) is radiated.

In the EUV exposure apparatus 700, the space where the EUV light 15 is irradiated needs to be maintained in a vacuum in order to prevent the EUV light 15 from being absorbed by a material. Therefore, a plurality of exhaust systems such as vacuum pumps are installed to the EUV exposure apparatus 700. The pressure in a chamber through which the EUV light 15 passes is equal to or less than 10⁻³ Pa, and it is preferable that the partial pressure of oxygen and moisture is low without limit.

The illumination optical system 200 includes a plurality of illumination optical system mirrors 16 and 17 (multilayer mirrors), an optical integrator (not shown), and the like. The role of the illumination optical system 200 is to efficiently condense the light which is radiated from the light source 100, and is to uniform the illuminance on an exposure area, and the like. The optical integrator also has a role of uniformly illuminating the reticle 6 (mask) with a predetermined numerical aperture.

The projection optical system 400 includes projection optical system mirrors 18 to 23. Each of the projection optical system mirrors 18 to 23 is a multilayer mirror which is coated by Mo and Si alternately. Since the multilayer has a reflectance of the directly incident EUV light is around 67%, most of the energy absorbed in the multilayer mirror changes to heat. Therefore, a low thermal expansion glass or the like is used as a substrate material of the projection optical system mirrors 18 to 23.

The reticle stage 8 and the wafer stage 11 have a mechanism which performs a drive in a vacuum environment and synchronously scan at a velocity rate which is proportional to the reduced magnification. The position and the attitude of the reticle stage 8 and the wafer stage 11 are observed and controlled by a laser interferometer (not shown). Each of the reticle stage 8 and the wafer stage 11 includes a micromotion mechanism and is capable of positioning the reticle 6 and the wafer 9, respectively.

An alignment detection mechanism includes a reticle alignment optical system 12 and a wafer alignment optical system 13. The reticle alignment optical system 12 and the wafer alignment optical system 13 measure the position relation between the reticle 6 and an optical axis of the projection optical system 400 and the position relation between the wafer 9 and the optical axis of the projection optical system 400, respectively. Based on the result, the position and the angle of the reticle stage 8 and the wafer stage 11 are adjusted so that a projection image of the reticle 6 coincides with a predetermined position on the wafer 9.

The focus position detection mechanism 14 detects a focus position on the wafer surface in a vertical direction in order to hold the image position of the projection optical system 400 on the wafer surface.

When one exposure is finished, the wafer stage 11 performs a step movement in an X direction and a Y direction and moves to a subsequent scanning exposure start position in order to perform the exposure again. At this time, a particle such as emitted gas, debris, a secondary electron, or a dust particle is generated inside the EUV exposure apparatus 700. When the particle adheres to an optical element, the surface of the optical element is polluted.

In the present embodiment, in order to prevent the particle from freely moving in and out of each unit, a wire electrode array 30 is positioned at openings 25 to 28 through which the exposure light passes, which are provided at boundaries of adjacent vacuum chambers (walls 45, 46, 47, and 48).

As shown in FIG. 1, the wire electrode array 30 is positioned at the opening 25 of the boundary between the light source space (the vacuum chamber 1) and the illumination optical system space (the vacuum chamber 2) and at the opening 26 of the boundary between the illumination optical system space (the vacuum chamber 2) and the reticle stage space (the vacuum chamber 3). The wire electrode array 30 is positioned at the opening 27 of the boundary between the reticle stage space (the vacuum chamber 3) and the projection optical system space (the vacuum chamber 4) and at the opening 28 of the boundary between the wafer stage space (the vacuum chamber 5) and the projection optical system space (the vacuum chamber 4).

Thus, the wire electrode array 30 which is provided at the opening of the boundary between the adjacent vacuum chambers can prevent the particle from freely moving in and out of each vacuum chamber (each unit).

Hereinafter, the specific embodiment of the wire electrode array 30 will be described.

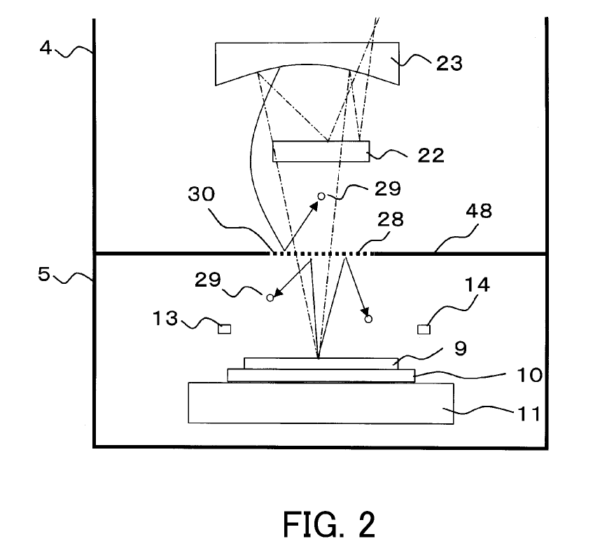

First, embodiment 1 of the present invention will be described. FIG. 2 shows a wafer stage space (a vacuum chamber 5) and a projection optical system space (a vacuum chamber 4) in an exposure apparatus of embodiment 1. In the present embodiment, the wire electrode array 30 is placed at the opening 28 through which the exposure light passes at the boundary between the wafer stage space (the vacuum chamber 5) and the projection optical system space (the vacuum chamber 4).

The wire electrode array 30 is constituted by a plurality of parallel wire electrodes. Two or more wire electrodes are arranged horizontally at regular intervals to be placed like mesh. The wire electrode array 30 includes a first wire electrode group to which an alternating voltage having a first phase is applied and a second wire electrode group to which an alternating voltage having a second phase which is different from the first phase is applied.

The wire electrode array 30 prevents an electrically-charged particle 29 from intruding into adjacent other spaces because alternating voltages which have phases differing from each other are applied to each electrode group. Thus, the wire electrode array 30 functions so as to bounce the electrically-charged particle 29, or functions as a non-contact electric field curtain which transfers the electrically-charged particle 29.

Therefore, the particle 29 generated in the wafer stage space (the vacuum chamber 5) does not intrude into the projection optical system space (the vacuum chamber 4) through the opening 28. Similarly, the particle 29 generated in the projection optical system space (the vacuum chamber 4) does not intrude into the wafer stage space (the vacuum chamber 5) through the opening 28.

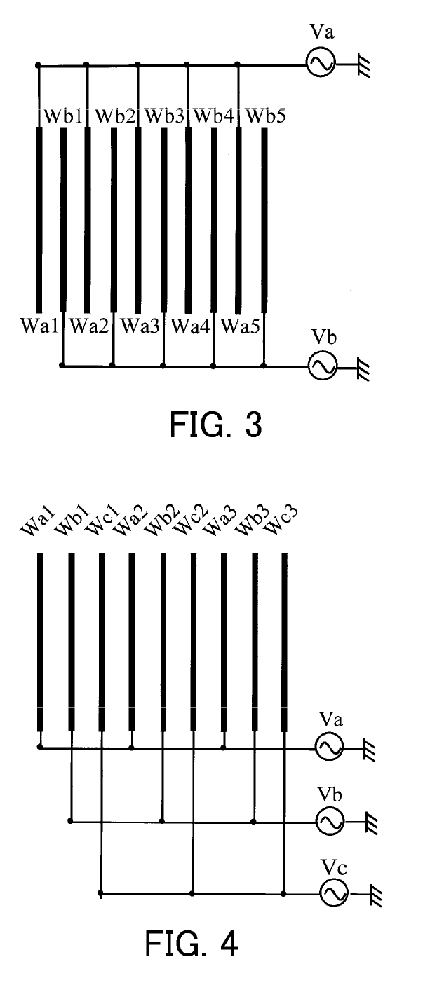

Next, the configuration of the wire electrode array and the effect thereof will be described. FIG. 3 shows a wire electrode array which is constituted by two wire electrode groups of a first wire electrode group Wa and the second wire electrode group Wb in the present embodiment.

The first wire electrode group Wa is constituted by a plurality of first wire electrodes Wa1 to Wa5. Similarly, the second wire electrode group Wb is constituted by a plurality of second wire electrodes Wb1 to Wb5. The first wire electrodes Wa1 to Wa5 constituting the first wire electrode group Wa and the second wire electrodes Wb1 to Wb5 constituting the second wire electrode group Wb are arranged alternately.

In FIG. 3, the first wire electrode group Wa is constituted by five first wire electrodes Wa1 to Wa5, and the second wire electrode group Wb is constituted by five second wire electrodes Wb1 to Wb5. However, the number of the first wire electrodes included in the first wire electrode group Wa and the second wire electrodes included in the second wire electrode group Wb is not limited to this. The first wire electrode group Wa may include at least one first wire electrode, and the second wire electrode group Wb may include at least one second wire electrode. However, it is preferable that the first wire electrode group Wa and the second wire electrode group Wb are constituted by a plurality of first wire electrodes and a plurality of second wire electrodes, respectively. The wire electrode array is, for example, constituted by around one hundred wire electrodes.

The first wire electrodes Wa1 to Wa5 and the second wire electrodes Wb1 to Wb5 are horizontally arranged at regular intervals to be placed like mesh. The first wire electrodes Wa1 to Wa5 constituting the first wire electrode group Wa are connected to an alternating power supply which applies an alternating voltage Va having a first phase. The second wire electrodes Wb1 to Wb5 constituting the second wire electrode group Wb are connected to an alternating power supply which applies an alternating voltage Vb having a second phase.

As a material of the first wire electrodes Wa1 to Wa5 and the second wire electrodes Wb1 to Wb5, for example, a stainless steel (SUS) is used. However, the present embodiment is not limited to this. Other materials which are durable and are capable of being thinned may be used. For example, gold (Au), platinum (Pt), chrome (Cr), nickel (Ni), or the like can also be used.

It is preferable that the wire diameter D and the wire interval P of the wire electrodes which are used for the exposure apparatus of the present embodiment satisfy D<100 μm and P>100 μm, respectively. For example, the wire electrode array is constituted by wire electrodes having the wire diameter D of 10 μm and the wire interval P of 250 μm. The exposure light tends to be attenuated as the wavelength is shorter. Therefore, if the exposure light which has a shorter wavelength is used, it is preferable that the wire diameter D is smaller and that the wire interval P is larger.

FIG. 4 shows a wire electrode array which is constituted by three wire electrode groups of a first wire electrode group Wa, a second wire electrode group Wb, and a third wire electrode group Wc.

The wire electrode array shown in FIG. 4 includes a third wire electrode group Wc to which an alternating voltage Vc having a third phase which is different from both the first and the second phases is applied, in addition to the first wire electrode group Wa and the second wire electrode group Wb.

The first wire electrodes Wa1 to Wa3, the second wire electrodes Wb1 to Wb3, and the third wire electrodes Wc1 to Wc3 are sequentially arranged. In other words, wire electrodes which constitute each wire electrode group are sequentially repeatedly arranged one by one.

As shown in FIG. 4, the first wire electrode group Wa and the second wire electrode group Wb are constituted by three wire electrodes Wa1 to Wa3 and three wire electrodes Wb1 to Wb3, respectively. Similarly, the third wire electrode group Wc is constituted by three wire electrodes Wc1 to Wc3. However, the number of the wire electrodes included in each wire electrode group is not limited to this. Each of the first wire electrode group, the second wire electrode group, and the third wire electrode group can include at least one wire electrode.

The first wire electrode Wa1 to Wa3, the second wire electrode Wb1 to Wb3, and the third wire electrode Wc1 to Wc3 are horizontally arranged at regular intervals to be placed like mesh. The first wire electrodes Wa1 to Wa3 constituting the first wire electrode group Wa are connected to an alternating current power supply which applies an alternating voltage Va of the first phase. The second wire electrodes Wb1 to Wb3 constituting the second wire electrode group Wb are connected to an alternating current power supply which applies an alternating voltage Vb of the second phase. The third wire electrodes Wc1 to Wc3 constituting the third wire electrode group We are connected to an alternating current power supply which applies an alternating voltage Vc of the third phase. The first, second, and third phases of the alternating voltages Va, Vb, and Vc, respectively, which are applied by each alternating current power supply are different from each other.

When the wire electrode array is constituted by three wire electrode groups, the wire electrode array functions so as to send an oncoming particle to one direction. Therefore, if the control is performed so as to introduce the particle in a certain direction, it is preferable that the wire electrode array is constituted by three or more wire electrode groups.

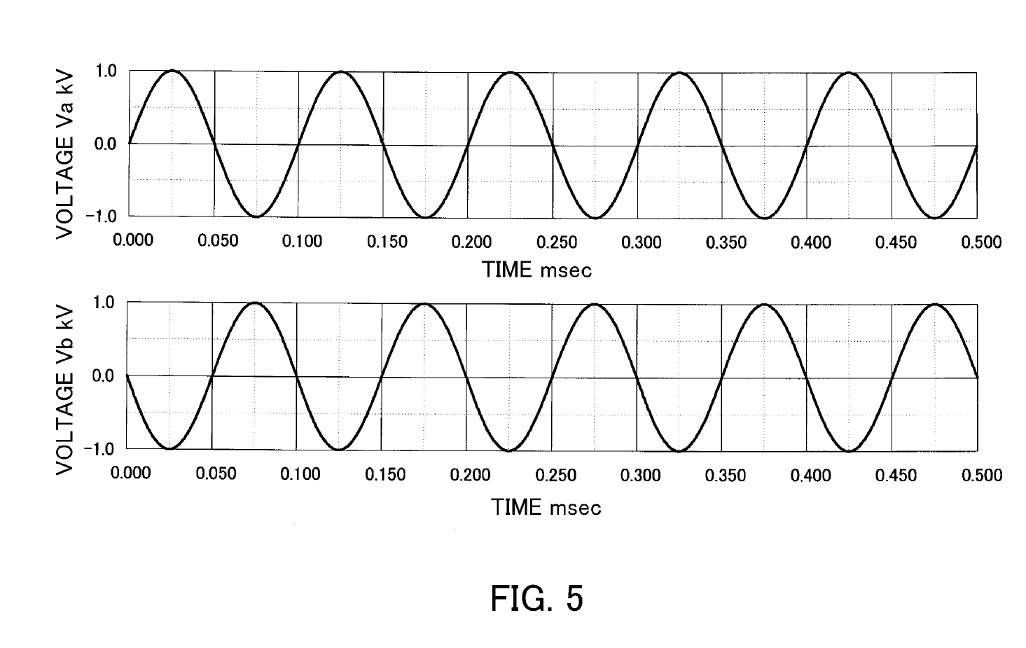

FIG. 5 is a waveform diagram of an alternating voltage which is applied to the wire electrode array constituted by two wire electrode groups shown in FIG. 3.

As shown in FIG. 3, the wire electrode array is constituted by the two electrode groups of the first wire electrode group Wa and the second wire electrode group Wb. Alternating voltages Va and Vb whose phases are different by 180° from each other are applied to the first wire electrode group Wa and the second wire electrode group Wb, respectively.

FIG. 5 shows a waveform of the alternating voltages Va and Vb which are applied to the first wire electrode group Wa and the second wire electrode group Wb, respectively. The alternating voltages Va and Vb have the phases which are different by 180° from each other under the condition of the voltage Vpp=2 kV, and the frequency f=10 kHz. Thus, it is preferable that the phase difference of the first phase applied to the first wire electrode group Wa and the second phase applied to the second wire electrode group Wb is 180°. However, the present embodiment is not limited to this, but the phase difference other than 180° may be set if the first phase and the second phase are controlled so as to differ from each other.

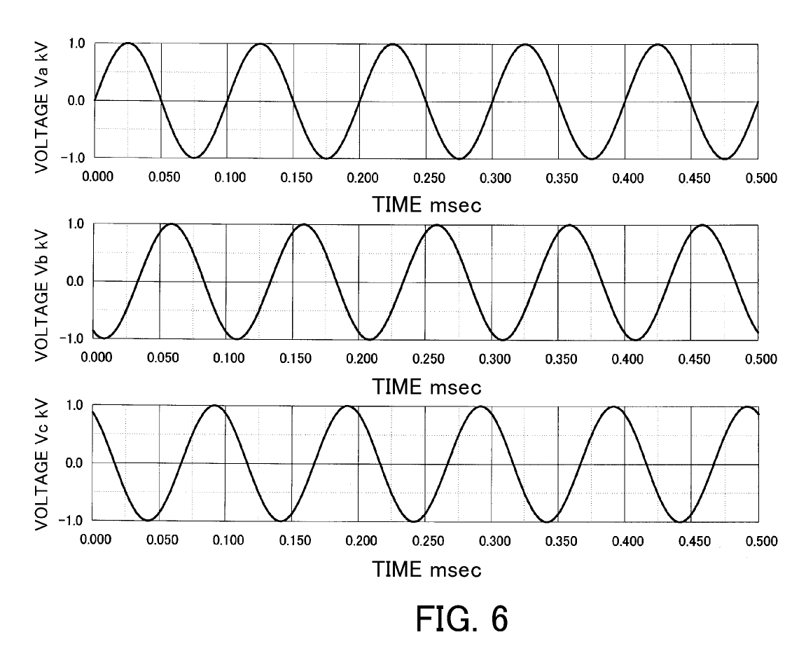

FIG. 6 is a waveform diagram of an alternating voltage which is applied to the wire electrode array constituted by the three wire electrode groups shown in FIG. 4.

As shown in FIG. 4, the wire electrode array is constituted by the three electrode groups of the first wire electrode group Wa, the second wire electrode group Wb, and the third wire electrode group Wc. Alternating voltages whose phases are different by 120° from each other are applied to the first wire electrode group Wa, the second wire electrode group Wb, and the third wire electrode group Wc, respectively.

FIG. 6 shows a waveform of the alternating voltages Va, Vb, and Vc which are applied to the first wire electrode group Wa, the second wire electrode group Wb, and the third wire electrode group Wc. The alternating voltages Va, Vb, and Vc have the phases which are different by 120° from each other under the condition of the voltage Vpp=2 kV and the frequency f=10 kHz. Thus, it is preferable that the phase difference between the first phase applied to the first wire electrode group Wa, the second phase applied to the second wire electrode group Wb, and the third phase applied to the third wire electrode group Wc is to be set to 120°. However, the present embodiment is not limited to this, but the phase difference other than 120° may be set if all of these three phases are controlled so as to differ from one another.

The number of the wire electrode groups is not limited to two or three, but four or more wire electrode groups can also be used. When the number of the wire electrode groups is generalized to N, it is preferable that alternating voltages whose phases differ by 360/N° from one another are applied to the wire electrode groups, respectively. However, the present embodiment is not limited to this, but the phase difference other than 360/N° may be set if each of the phases of the alternating voltages applied to each of the N wire electrode groups are controlled so as to differ from one another.

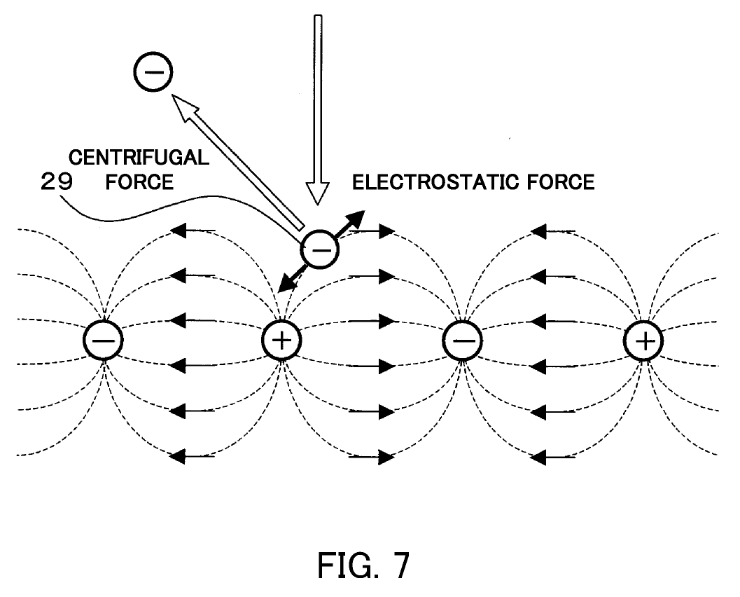

Next, referring to FIG. 7, the effect which is obtained when the wire electrode array is constituted by two wire electrode groups will be described.

The phases of the two wire electrode groups (the first wire electrode group Wa and the second wire electrode group Wb) differ by 180° from each other. Therefore, reverse voltages are applied to two adjacent wire electrodes, respectively, and an electric potential gradient is generated between the wire electrodes. When the electrically-charged particle 29 comes close to the wire electrode array, the particle 29 receives an electrostatic force by the electric potential gradient generated by the two adjacent wire electrodes. The direction in which this electrostatic force acts is a tangential direction of a line of electric force which is formed between the two wire electrodes adjacent to the particle 29.

An alternating voltage is applied to both the wire electrode groups. Therefore, plus and minus of the voltage applied to the wire electrode is switched as time passes. In other words, as time passes, the direction of the electrostatic force acting to the particle 29 is reversed, and the particle 29 oscillates by receiving the electrostatic force at a constant position. The line of electric force between two wire electrodes is a curve line which is convex outward at a position other than the surface of the wire electrode array. Therefore, the centrifugal force is generated in the oscillated particle 29, and it is bounced from the wire electrode array. Thus, the electrically-charged particle 29 which comes close to the wire electrode array can not intrude to the space which is placed at opposite side with respect to a wire electrode surface.

When the phase difference of the two wire electrode groups is set to 180°, the voltages applied to both wire electrode groups are zero at certain times. Therefore, it is preferable that the frequency of the alternating voltages which are applied to the two wire electrode groups is set to be higher. The period of time in which the voltage is not applied to the two wire electrode groups can be shortened by heightening the frequency of the alternating voltage.

The effect which is obtained when the wire electrode array is constituted by three or more wire electrode groups is as follows.

When the alternating voltages which differ in phase from one another are applied to the three or more wire electrode groups, a traveling wave type non-uniform electric field is obtained on the surface constituting the wire electrode of the wire electrode array. When the electrically-charged particle 29 comes close to the wire electrode array, the particle is held at a position away to some extent from the wire electrode surface to be transferred in a direction parallel to the wire electrode surface by the traveling wave type non-uniform electric field. Therefore, the electrically-charged particle 29 which comes close to the wire electrode array can not intrude to the space which is placed at an opposite side with respect to the wire electrode surface.

As described above, when the exposure light enters the wafer 9 on which a resist is coated, the emitted gas is generated. The emitted gas is scattered from the wafer stage space (the vacuum chamber 5) to the projection optical system space (the vacuum chamber 4), and adheres to the optical element and causes the optical performance to be deteriorated. A part of the emitted gas is electrically-charged by the action for the exposure light.

As shown in FIG. 2, the wire electrode array 30 is placed at the opening 28 through which the exposure light passes at the boundary (the wall 48) of the wafer stage space (the vacuum chamber 5) and the projection optical system space (the vacuum chamber 4). The wire electrode array 30 can prevent the electrically-charged emitted gas from intruding from the wafer stage space (the vacuum chamber 5) to the projection optical system space (the vacuum chamber 4) via the opening 28.

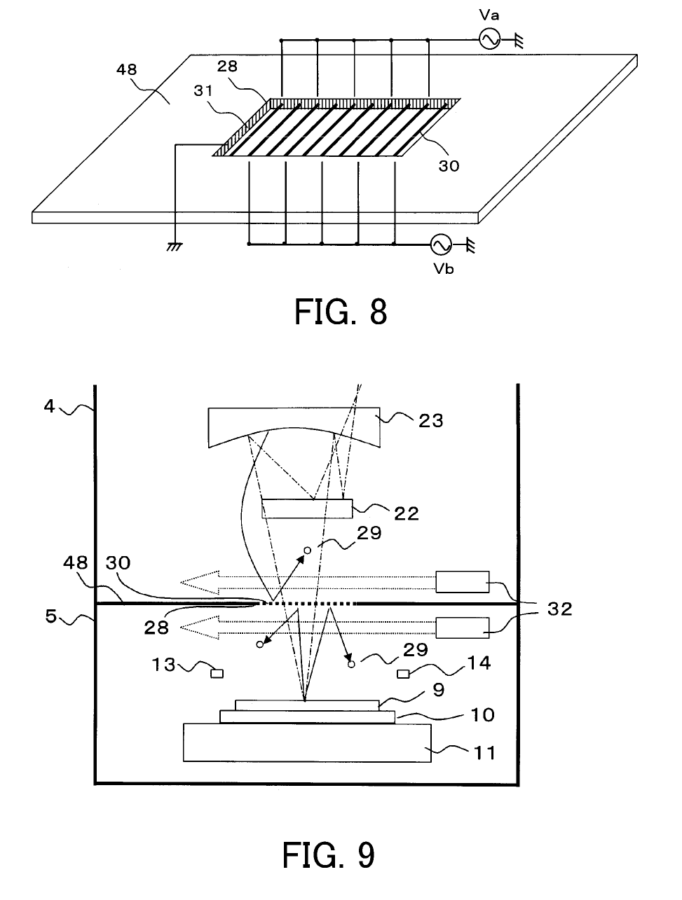

FIG. 8 is a configuration diagram of the opening 28 through which the exposure light passes at the boundary of the wafer stage space (the vacuum chamber 5) and the projection optical system space (the vacuum chamber 4).

The side wall 31 of the opening 28 is covered by metal and is grounded at a ground potential (GND). Thus, since the metal grounded at the ground potential surrounds the wire electrode array 30 in a horizontal direction of the wire electrode surface, it is suppressed that the electric field formed by the wire electrode array 30 generates an electric noise to influence at an area distant from the wire electrode array 30.

The wire electrode is insulated with respect to the metal part of the side wall 31 of the opening 28. When the member of the side wall 48 constituting the boundary of the wafer stage space (the vacuum chamber 5) and the projection optical system space (the vacuum chamber 4) is made of metal, the wall 48 itself is grounded at the ground potential. On the other hand, when the wall 48 is integrated with the exposure apparatus, the exposure apparatus is grounded at the ground potential.

It is highly likely that a dust particle generated from a stage moving unit or the like which exists in the wafer stage space (the vacuum chamber 5) or a dust particle adhered to the wafer during the transfer process and scattered again to the wafer stage space (the vacuum chamber 5) can be electrically-charged during the generating process. Therefore, the wire electrode array 30 can prevent the electrically-charged dust particle from intruding from the wafer stage space (the vacuum chamber 5) to the projection optical system space (the vacuum chamber 4).

As described above, according to the configuration of the present embodiment, the pollution of the optical element in the projection optical system space via the opening 28 by the electrically-charged emitted gas or the dust particle can be effectively prevented. In particular, according to the configuration of the present embodiment, the pollution by both the positively and negatively electrically-charged emitted gas and the dust particle can be prevented.

The projection optical system mirrors 18 to 23 which are placed in the projection optical system space (the vacuum chamber 4) emit a secondary electron by entering the exposure light. When the secondary electron adheres to the optical element, the optical performance is deteriorated. The wire electrode array 30 which is placed at the boundary between the wafer stage space (the vacuum chamber 5) and the projection optical system space (the vacuum chamber 4) can prevent the secondary electron from intruding from the projection optical system space (the vacuum chamber 4) to the wafer stage space (the vacuum chamber 5).

The intrusion of the positively or negatively charged dust particle which is generated in the projection optical system space (the vacuum chamber 4) from the projection optical system space (the vacuum chamber 4) to the wafer stage space (the vacuum chamber 5) can also be prevented. Thus, according to the present embodiment, the pollution of the wafer via the opening 28 by the secondary electron or the electrically-charged dust particle can be effectively prevented. According to the present embodiment, the intrusion of the particle 29 in two-way directions via the opening 28 can be prevented.

Next, the effect of the wire electrode array 30 with respect to the transmittance of the exposure light will be described.

In the exposure apparatus of the present embodiment, if the wire diameter D and the wire interval P of each of the wire electrodes satisfy D<100 μm and P>100 μm, respectively, illuminance deterioration of the exposure light is adequately small. In other words, even if the wire electrode array 30 is placed at the boundary of the wafer stage space (the vacuum chamber 5) and the projection optical system space (the vacuum chamber 4), the intrusion of the particle 29 can be prevented in a state where the transmittance of the exposure light is maintained.

The wire electrode array 30 acts on the particle 29 as a non-contact electric field curtain. Therefore, the wire electrode array 30 itself is not substantially deteriorated, and the shielding function of the particle continues to be maintained. In other words, the wire electrode array 30 acts as a particle shielding apparatus which does not need a periodic replacement and the throughput of the exposure apparatus is not reduced.

In the present embodiment, although the wire electrode array 30 is placed at the opening 28 through which the exposure light passes at the boundary between the wafer stage space (the vacuum chamber 5) and the projection optical system space (the vacuum chamber 4), the position to be placed is not limited to this. As described above, the wire electrode array can be placed anywhere if it is placed at a boundary between the vacuum chamber (unit) in the exposure apparatus where the particle 29 is generated and another adjacent vacuum chamber (unit).

Generally, in such a boundary, a minimum opening required for the exposure light passing through is provided. Debris, a secondary electron, and a dust particle can be generated in the light source space (the vacuum chamber 1), the illumination optical system space (the vacuum chamber 2) and the projection optical system space (the vacuum chamber 4), and the reticle stage space (the vacuum chamber 3), respectively.

Thus, as another position where the wire electrode array 30 is preferably placed, an opening 25 at the boundary between the light source space (the vacuum chamber 1) and the illumination optical system space (the vacuum chamber 2) is considered. Furthermore, it is preferable that the wire electrode array 30 is also placed at an opening 26 at the boundary between the illumination optical system space (the vacuum chamber 2) and the reticle stage space (the vacuum chamber 3) and an opening 27 at the boundary between the reticle stage space (the vacuum chamber 3) and the projection optical system space (the vacuum chamber 4).

As described above, according to the configuration of the present embodiment, free movement of the particle via the boundary between adjacent vacuum chambers (units) can be effectively prevented. Even if the wire electrode array is placed at these boundaries, the transmittance of the exposure light is maintained, and the transmittance is not substantially reduced.

Next, embodiment 2 of the present invention will be described. FIG. 9 is a configuration diagram of the wafer stage space (the vacuum chamber 5) and the projection optical system space (the vacuum chamber 4) in an exposure apparatus of embodiment 2.

The exposure apparatus of the present embodiment differs from that of embodiment 1 in that an ionizer 32 which ionizes the particle 29 generated inside the vacuum chambers 4 and 5 is placed in the vacuum chambers 4 and 5.

As an ionizer 32 of the present embodiment, for example, a laser light source, a UV lamp, an electron beam source, an ion beam source, or the like is used. The ionizer 32 actively ionizes or charges the particle 29 such as the emitted gas on the way to the wire electrode array 30. As an amount of the charge of the particle 29 increases, the electrostatic force which acts on the particle 29 increases and the particle shielding effect of the wire electrode array 30 is heightened.

It is preferable that the ionizer 32 is placed at the position where it can irradiate the ionized beam to the particle 29 which scatters toward the wire electrode array 30. If it is in the wafer stage space (the vacuum chamber 5), it is preferable that the ionized beam is irradiated between the vicinity of the wafer 9 and the wire electrode array 30. In the projection optical system space (the vacuum chamber 4), it is preferable that the ionized beam is irradiated at the vicinity of the projection optical system mirrors 18 to 23 or at the vicinity of the wire electrode array 30.

In the present embodiment, the ionizer 32 in the case where the wire electrode array 30 is placed at the boundary between the wafer stage space (the vacuum chamber 5) and the projection optical system space (the vacuum chamber 4) has been described. However, the setting place of the ionizer 32 of the present embodiment is not limited to this. The wire electrode array 30 can be placed at a position other than the boundary between the wafer stage space (the vacuum chamber 5) and the projection optical system space (the vacuum chamber 4).

In such a configuration, for example, the ionizer 32 can be placed at the vicinity of each of the wire electrode arrays, at the vicinity of the target material 24 of the light source space (the vacuum chamber 1), at the vicinity of the illumination optical system mirrors 16 and 17 of the illumination optical system space (the vacuum chamber 2), at the vicinity of the reticle stage 8 of the reticle stage space (the vacuum chamber 3), or the like. Thus, it is preferable that the ionizer 32 is placed at the position where it can irradiate the ionized beam to the particle 29 which scatters toward the wire electrode array 30.

According to the configuration of the present embodiment, the particle shielding effect of the wire electrode array 30 can be heightened by irradiating the ionized beam to the particle 29 which moves to the wire electrode array 30.

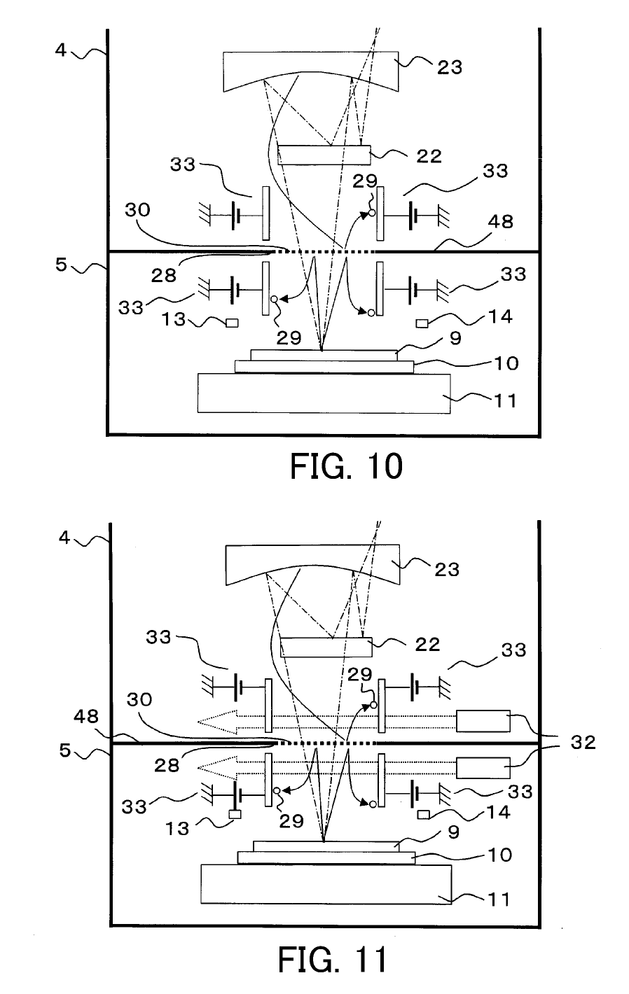

Next, embodiment 3 of the present invention will be described. FIG. 10 is a configuration diagram of the wafer stage space (the vacuum chamber 5) and the projection optical system space (the vacuum chamber 4) in an exposure apparatus of embodiment 3.

The exposure apparatus of the present embodiment differs from that of embodiment 1 in that an auxiliary electrode which captures the electrically-charged particle 29 existing in the vacuum chambers 4 and 5 is provided in the vacuum chambers 4 and 5.

The auxiliary electrode 33 prevents the particle 29 from adhering again to the optical element by immediately capturing the particle 29 such as ionized emitted gas bounced by the wire electrode array 30. As shown in FIG. 10, a pair of auxiliary electrodes 33 which is positively or negatively charged is provided in each of the wafer stage space (the vacuum chamber 5) and the projection optical system space (the vacuum chamber 4). In other words, the auxiliary electrode 33 which is positively charged is placed at the right side of FIG. 10, and the auxiliary electrode 33 which is negatively charged is placed at the left side.

In the present embodiment, since the pair of the auxiliary electrodes 33 which is positively or negatively charged is placed at the vicinity of the wire electrode array 30, the charged particle 29 bounced by the wire electrode array 30 is captured by the auxiliary electrode 33 regardless of the positive or the negative particle. In other words, the positively charged particle 29 is captured by the negatively charged auxiliary electrode 33, and the negatively charged particle 29 is captured by the positively charged auxiliary electrode 33.

In the exposure apparatus of the present embodiment, the auxiliary electrode 33 in the case where the wire electrode array 30 is placed at the boundary between the wafer stage space (the vacuum chamber 5) and the projection optical system (the vacuum chamber 4) has been described. However, the present embodiment is not limited to this, but the wire electrode array 30 can also be placed at another unit boundary (a boundary of adjacent vacuum chambers).

Also in such a configuration, since the pair of the auxiliary electrode 33 which is positively or negatively charged is placed at the vicinity of the wire electrode array 30, it can prevents the particle 29 bounced by the wire electrode array 30 and charged from adhering again to the optical element.

Next, embodiment 4 of the present invention will be described. FIG. 11 is a configuration diagram of the wafer stage space (the vacuum chamber 5) and the projection optical system space (the vacuum chamber 4) in an exposure apparatus of embodiment 4.

The exposure apparatus of the present embodiment differs from that of embodiment 1 in that the ionizer 32 similar to that of embodiment 2 and the auxiliary electrode 33 similar to that of embodiment 3 are placed inside the vacuum chambers 4 and 5.

In the present embodiment, the ionizer 32 and the auxiliary electrode 33 are placed at the vicinity of the wire electrode array 30. The ionizer 32 can heighten both the particle shielding effect of the wire electrode array 30 and the particle capturing effect of the auxiliary electrode 33 by actively charging the particle 29.

In the present embodiment, the ionizer 32 and the auxiliary electrode 33 in the case where the wire electrode array 30 is placed at the boundary between the wafer stage space (the vacuum chamber 5) and the projection optical system space (the vacuum chamber 4) have been described. However, the present embodiment is not limited to this, but the ionizer 32 and the auxiliary electrode 33 can also be placed at the vicinity of the wire electrode array 30 which is provided at the boundary of other units (the boundary between adjacent vacuum chambers) as described in embodiments 3 and 4. The ionizer 32 can also be placed at the position where it can irradiate the scattering particle 29. Since the ionizer 32 and the auxiliary electrode 33 are placed at the vicinity of the wire electrode array 30 provided at another unit boundary, the particle shielding effect of the wire electrode array 30 and the particle capturing effect of the auxiliary electrode can also be heightened for another unit boundary.

The exposure apparatus of each of the above embodiments is suitably used, for example, for manufacturing devices which have fine patterns such as semiconductor devices. In particular, each of the above embodiments is suitably used for an exposure apparatus which performs an exposure using light of short wavelength 0.5 to 50 nm such as EUV light or for an exposure apparatus which performs an exposure using an optical element such as a mirror or a lens in a high-vacuum environment.

A device (a semiconductor integrated circuit device, a liquid crystal display device, or the like) is manufactured by a process of exposing a substrate (a wafer, a glass plate, or the like) coated by a photosensitizing agent using the exposure apparatus of one of the above embodiments, a process of developing the substrate, and other well-known processes.

According to each of the above embodiments, an exposure apparatus which can prevent an optical element from being polluted by a particle such as emitted gas, debris, a secondary electron, or a dust particle in an EUV exposure apparatus freely moving in and out of each unit in a state where the transmittance of the exposure light is maintained can be provided. According to each of the above embodiments, a device manufacturing method with high accuracy using the exposure apparatus can also be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-088786, filed on Mar. 28, 2008, which is hereby incorporated by reference herein in its entirety.

What is claimed is:

1. An exposure apparatus configured to expose a circuit pattern formed on an original plate onto a substrate in a vacuum environment, the exposure apparatus comprising:
a plurality of vacuum chambers which separate inside of the exposure apparatus into a plurality of areas; and
a wire electrode array having a plurality of parallel wire electrodes,
wherein the wire electrode array is placed at an opening through which exposure light passes at a boundary between the adjacent vacuum chambers, and has a first wire electrode group to which an alternating voltage of a first phase is applied and a second wire electrode group to which an alternating voltage of a second phase differing from the first phase is applied.

2. An exposure apparatus according to claim 1,
wherein the first wire electrode constituting the first wire electrode group and the second wire electrode constituting the second wire electrode group are alternately arranged.

3. An exposure apparatus according to claim 1,
wherein the wire electrode array further has a third wire electrode group to which an alternating voltage of a third phase differing from the first phase and the second phase is applied.

4. An exposure apparatus according to claim 3,
wherein a first wire electrode constituting the first wire electrode group, a second wire electrode constituting the second wire electrode group, and a third wire electrode group constituting the third wire electrode group are sequentially arranged.

5. An exposure apparatus according to claim 1,
wherein the wire electrode array is placed at the opening provided at the boundary between a vacuum chamber which houses a wafer stage and a vacuum chamber which houses a projection optical system among the plurality of vacuum chambers.

6. An exposure apparatus according to claim 1,
wherein the wire electrode array is placed at the opening provided at the boundary between a vacuum chamber which houses a reticle stage and a vacuum chamber which houses an illumination optical system among the plurality of vacuum chambers.

7. An exposure apparatus according to claim 1,
wherein the wire electrode array is placed at the opening provided at the boundary between a vacuum chamber which houses an illumination optical system and a vacuum chamber which houses a light source among the plurality of vacuum chambers.

8. An exposure apparatus according to claim 1,
wherein an ionizer configured to ionize a particle generated inside the vacuum chamber is placed in the vacuum chamber.

9. An exposure apparatus according to claim 1,
wherein an auxiliary electrode configured to capture an electrically-charged particle which exists inside the vacuum chamber is placed in the vacuum chamber.

10. A device manufacturing method comprising the steps of:
exposing a substrate using an exposure apparatus; and
developing the exposed substrate,
wherein the exposure apparatus is configured to expose a circuit pattern formed on an original plate onto a substrate in a vacuum environment, the exposure apparatus comprising:
a plurality of vacuum chambers which separate inside of the exposure apparatus into a plurality of areas; and
a wire electrode array having a plurality of parallel wire electrodes,
wherein the wire electrode array is placed at an opening through which exposure light passes at a boundary between adjacent vacuum chambers, and has a first wire electrode group to which an alternating voltage of a first phase is applied and a second wire electrode group to which an alternating voltage of a second phase differing from the first phase is applied.
